(19) United States
(12) Patent Application Publication
(10) Pub. No.: US 2009/0086448 A1
(43) Pub. Date: Apr. 2, 2009

(54) SOLID STATE DRIVE WITH COVERLESS CASING

(76) Inventors: Siew S. HIEW, San Jose, CA (US); Jim NI, San Jose, CA (US); Abraham Chih Keng Ma, Fremont, CA (US); Qi Jin Li, Irvine, CA (US)

Correspondence Address: SINORICA, LLC, 528 FALLSGROVE DRIVE, ROCKVILLE, MD, 20850, US

(21) Appl. No.: 11/863,225

(22) Filed: Sep. 27, 2007

(51) Int. Cl. H05K 5/02

(52) U.S. Cl. 361/753; 361/220; 361/757

(57) ABSTRACT

The present invention discloses a solid state drive with a coverless casing, which comprises: a printed circuit board assembly and a coverless casing. In the resent invention, the coverless casing is free of a top cover; thereby, air circulation can be enhanced to cool down the electronic components on a printed circuit board assembly more efficiently. Further, in the present invention, the coverless casing is designed to have the printed circuit board assembly electrically connected to the chassis ground of the host system via the coverless casings; thereby, unwanted electrostatic charges can be dissipated to the chassis ground of the host system before it can damage the electronic components on the printed circuit board assembly; thus, the ESD resistance thereof is promoted. Furthermore, the solid state drive with a coverless casing of the present invention is made of lightweight materials and easy to fabricate and simple to assemble; therefore, the present invention have the advantages of light weight and low cost.

### BACKGROUND OF THE INVENTION

1. Field of the Invention

The present invention relates to a solid state drive, particularly to a solid state drive with a coverless casing.

2. Description of the Related Art

An SSD (Solid State Drive) is a non-volatile data storage device or a flash memory to store permanent data. Conventional hard drives are also widely used to store permanent data. However, a conventional hard drive has a slower data access speed because of the mechanical moving parts thereof. The absence of rotating disks and mechanical devices in an SSD greatly improves the problems of EMI (Electro Magnetic Interference), physical shock resistance and reliability. However, a solid state drive is more prone to be damaged by ESD (Electro Static Discharge). In contrast, a conventional hard drive has a higher ESD resistance because the recording material thereof is made of a metallic material.

As higher and higher density memory is being compacted into the ever-shrinking SSD dimensions, heat has becomes an issue to SSD performance. Thus, better heat conduction packages or cases will gain prominence and popularity.

A US patent US2007/0183209A1 disclosed a “Thin Hard Drive with 2-Piece Casing and Ground Pin Standoff to reduce ESD Damage to Stacked PCBA's”, which has a design of triple-axis case-grounding tabs. The triple-axis case-grounding tabs draw any ESD (Electro-Static Discharge) current off the upper case along a primary axis and onto a PCBA (Printed Circuit Board Assembly) ground through a secondary axis that is screwed into the PCBA. An intermediary axis between the primary and secondary axes fits around a PCBA notch while the secondary axis passes through a metallized alignment hole on the PCBA for grounding. When the SATA connector is inserted into a host, the host ground sinks ESD current collected by the triple-axis case-grounding tabs.

The conventional technology mentioned above can indeed reduce ESD Damage to PCBA. However, the PCBA is encased inside an upper case and a lower case, and such an encapsulation of PCBA results in poor air circulation and inferior heat conduction, which will degrade the performance of the hard disc drive.

Accordingly, the present invention proposes a solid state drive with a coverless casing, which not only has superior ESD resistance but also has improved air circulation, to solve the problem mentioned above.

### SUMMARY OF THE INVENTION

One objective of the present invention is to provide a solid state drive with a coverless casing, which is characterized in the coverless casing thereof and applies to a desktop computer, a notebook computer, or other portable electronic devices needing a memory drive.

Another objective of the present invention is to provide a solid state drive with a coverless casing, wherein the coverless casing is free of a top cover; air circulation and heat conduction is thus enhanced to faster dissipate heat away from the printed circuit board assembly thereof.

Still another objective of the present invention is to provide a solid state drive with a coverless casing, wherein the printed circuit board assembly thereof is electrically connected to the chassis ground of the host system via the coverless casings; thereby, electrostatic charges can be dissipated to the chassis ground of the host system before electrostatic charges can damage the electronic components on the printed circuit board assembly; and the ESD resistance thereof is thus promoted.

Further another objective of the present invention is to provide a solid state drive with a coverless casing, which is made of lightweight materials and easy to fabricate and simple to assemble and thus has the advantages of light weight and low cost.

To achieve the abovementioned objectives, the present invention proposes a solid state drive (SSD) with a coverless casing, which is accommodated in the internal frame structure of a host system and comprises: a printed circuit board assembly (PCBA) and a coverless casing, wherein the printed circuit board assembly has a circuit board (PCB) having a plurality of board screw holes clad by ground planes, and the coverless casing accommodates the printed circuit board assembly thereinside. As the SSD with a coverless casing of the present invention is free of a top cover, air circulation can be enhanced to faster dissipate heat away from the SSD.

In one embodiment of the present invention, the coverless casing is a one-piece metallic coverless casing fabricated with a die-casting process. In this embodiment, after the PCBA has been installed in the coverless casing, and after the coverless casing has been fastened to the internal frame structure of the host system, the solid state drive with a coverless casing of the present invention has an electrical path to dissipate electro-static charges from the PCBA to the chassis ground of the host system before electro-static charges can damage the electronic components on the PCBA. In this embodiment, the coverless casing further comprises a plurality of screw poles; the screw poles are designed to seat another device in the same host system and also serve as alignment guides for the PCBA to sit at the precise position in the coverless casing.

In another embodiment of the present invention, the coverless casing is a one-piece plastic coverless casing fabricated with an injection-molding process. In this embodiment, at least one ground pin standing post is used to electrically connect the PCBA to a chassis ground of the host system to drain harmful electro-static charges to the chassis ground of the host system before electro-static charges strikes the electronic components of the PCBA.

In yet another embodiment of the present invention, the coverless casing is a hybrid coverless casing comprising: a plastic frame and a sheet metal bottom, wherein the sheet metal bottom is snap-fitted to the plastic frame to form the hybrid coverless casing. The sheet metal bottom has a plurality of snap hook fingers, which are arranged around the edges of the sheet metal bottom and erected at a 90 degree angle with respect to the sheet metal bottom. The plastic frame has a matching number of female slots built at corresponding positions to allow the snap hook fingers to snap thereinto to form the hybrid coverless casing.

In still another embodiment of the present invention, the coverless casing is a hybrid coverless casing comprising: a die-cast metallic frame and a sheet metal bottom. The hybrid coverless casing of this embodiment is basically similar to the abovementioned hybrid coverless casing except a die-cast metallic frame replaces the plastic frame.

In further another embodiment of the present invention, the coverless casing is a hybrid coverless casing comprising: a plastic inner frame, an aluminum-extrusion piece, and a plastic end plug, and wherein the PCBA is fastened to the plastic inner frame to form a sub-assembly; the sub-assembly is slid into and fastened to the aluminum extrusion piece, and the end of the plastic inner frame is plugged up with the end plug.

Below, the embodiments will be described in detail in cooperation with the attached drawings to make easily understood the objectives, technical contents, characteristics and accomplishments of the present invention.

### BRIEF DESCRIPTION OF THE DRAWINGS

FIG. 1 is a perspective view schematically showing an appearance of a solid state drive with a coverless casing according to the present invention;

FIG. 2 is an exploded view schematically showing a first embodiment of the present invention;

FIG. 3A is an exploded view schematically showing a second embodiment of the present invention;

FIG. 3B is a locally-enlarged view of FIG. 3A;

FIG. 4 is an exploded view schematically showing a third embodiment of the present invention;

FIG. 5 is an exploded view schematically showing a fourth embodiment of the present invention; and

FIG. 6 is an exploded view schematically showing a fifth embodiment of the present invention.

### DETAILED DESCRIPTION OF THE INVENTION

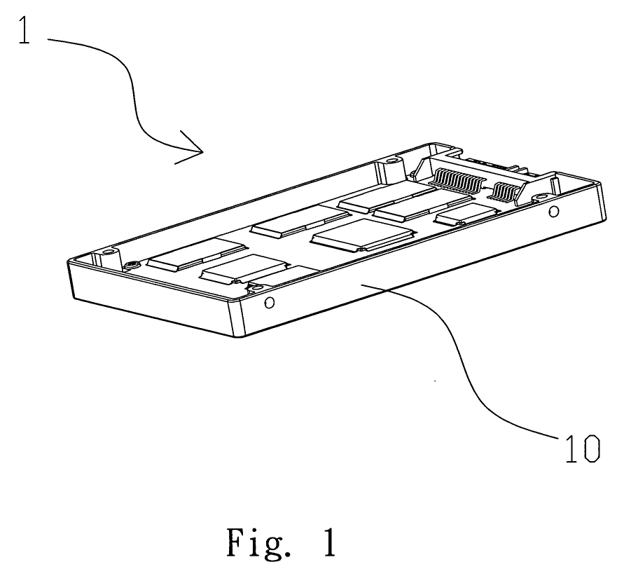

Refer to FIG. 1. The present invention proposes a solid state drive 1 with a coverless casing 10, which is accommodated in the internal frame structure of a host system and characterized in the coverless casing 10 thereof. The present invention applies to a desktop computer, a notebook computer, or other portable electronic devices needing a memory drive.

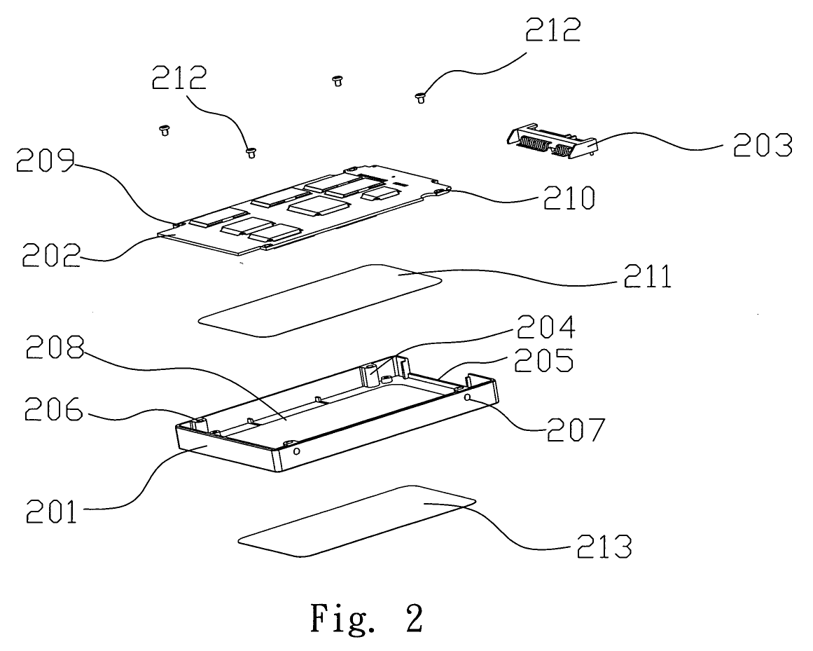

Refer to FIG. 2 for an exploded view schematically showing a first embodiment of the present invention. The present invention proposes a solid state drive 1, which comprises: a coverless casing 201, a printed circuit board assembly (PCBA) 202, and a pin connector 203.

The coverless casing 201 is a one-piece metallic coverless casing fabricated with a die-casting process. The metallic materials of the coverless casing 201 include metals suitable for die-casting fabrication, and aluminum is a choice material here due to its light weight and relatively lower melting point to do die casting. The surface of the coverless casing 201 may be painted with black or color paint. The coverless casing 201 may also have a higher-end finishing via electroplating a thin layer of metal, such as chromium (Cr), on its surface.

The coverless casing 201 has four screw poles 204, an opened gap 205, four first screw holes 206 and four second screw holes 207. The screw poles 204 are designed to seat another device in the same host system and also serve as alignment guides for the PCBA 202 to sit at the precise position in a cavity 208 of the coverless casing 201. The opened gap 205 is arranged at the back end wall of the coverless casing 201 and allows the pin connector 203 to precisely fit thereinto. Further, the connector interfaces for IDE, PCIE, etc., are also applicable to this open gap 205. The four first screw holes 206 are distributed at the four inner corners of the coverless casing 201; screws are screwed into PCB screw holes 209 and the first screw holes 206 to fasten the printed circuit board assembly 202 firmly to the coverless casing 201. The four second screw holes 207 are arranged at both lengthwise sides of the coverless casing 201; screws are screwed into the second screw holes 207 and the screw holes of the internal frame structure to anchor the coverless casing 201 to the internal frame structure of the host system and electrically connect the coverless casing 201 to a chassis ground of the host system.

This PCBA 202 further comprises: a PCB 210, connector pins, flash memory chips, controller chips, a SATA-to-IDE bridge, voltage regulators, voltage detectors, oscillator, and passive components. The electronic components mentioned above are soldered onto the PCB 210 with an SMT (Surface Mount Technology) process. A higher density SSD may utilizes both sides of the PCB 210 to pack more memories in the same drive.

In assembling the solid state drive with a coverless casing of the present invention, a piece of double side tape 211 is pasted on the surface of the cavity 208 of the coverless casing 201 and serves as both an adhesive layer and an insulating layer for the PCBA 202. Alternatively, the insulating layer may also be made of a material isolating the metallic coverless casing 201 from the electronic components on PCBA 202, such as a plastic, a rubber or a paper material. Next, the PCBA 202 is lowered down into the cavity 208 of the coverless casing 201, and four PCB screw holes 209 are aligned to the first screw holes 206 of the coverless casing 201. The PCBA 202 bottom surface thus adheres to the cavity 208 firmly via the double side tape 211. Next, four screws 212 are screwed into the PCB screw holes 209 and the first screw holes 206 to fasten the PCBA 202 firmly to the coverless casing 201; plastic, rubber or metal washers may be used to prevent the screws 212 from loosening and drop-off. Next, a label 213 with a company logo, memory size, bar code and other customer requested information is pasted on the bottom surface of the coverless casing 201. Thus, the assembly of a solid state drive 1 is completed.

Besides, a plurality of leveling posts projecting from the inner side walls may be used to replace the double side tape 211 to separate the PCBA 202 from the bottom of the coverless casing 201 and support the PCBA 202 at an elevated position.

Further, the screw poles 204 also allow another solid state drive to be seated therein to form a memory drive stack.

The PCB 210 is designed to have ground planes surrounding all the four PCB screw holes 209. After the screws 212 are screwed into the PCB screw holes 209 and the first screw holes 206 of the metallic coverless casing 201, the metallic coverless casing 201 is electrically connected with PCBA 202. Thereby, the solid state drive with a coverless casing of the present invention has an electrical path to dissipate unwanted electro-static charges to the chassis ground of the host system before electro-static charges can damage the electronic components on the PCBA.

As the SSD with a coverless casing of the present invention is free of a top cover, air circulation can be enhanced to faster dissipate heat away from the SSD.

The SSD with a metallic coverless casing of the present invention can apply to a desktop computer, a notebook computer, or other portable electronic devices needing a memory drive.

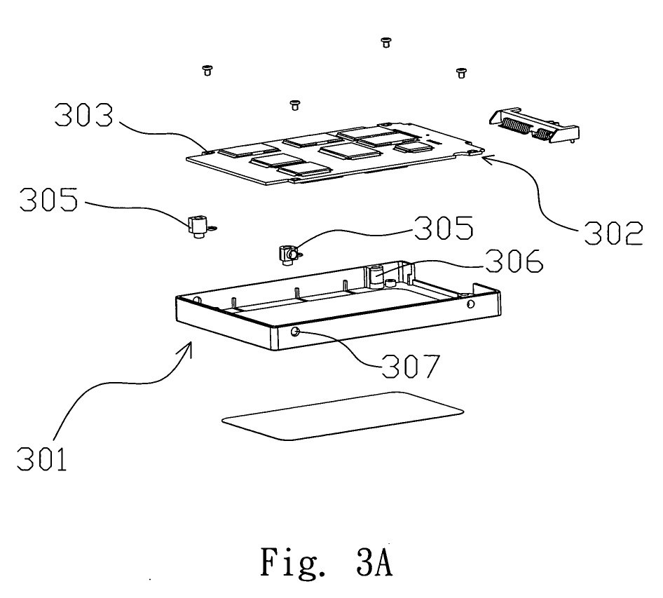

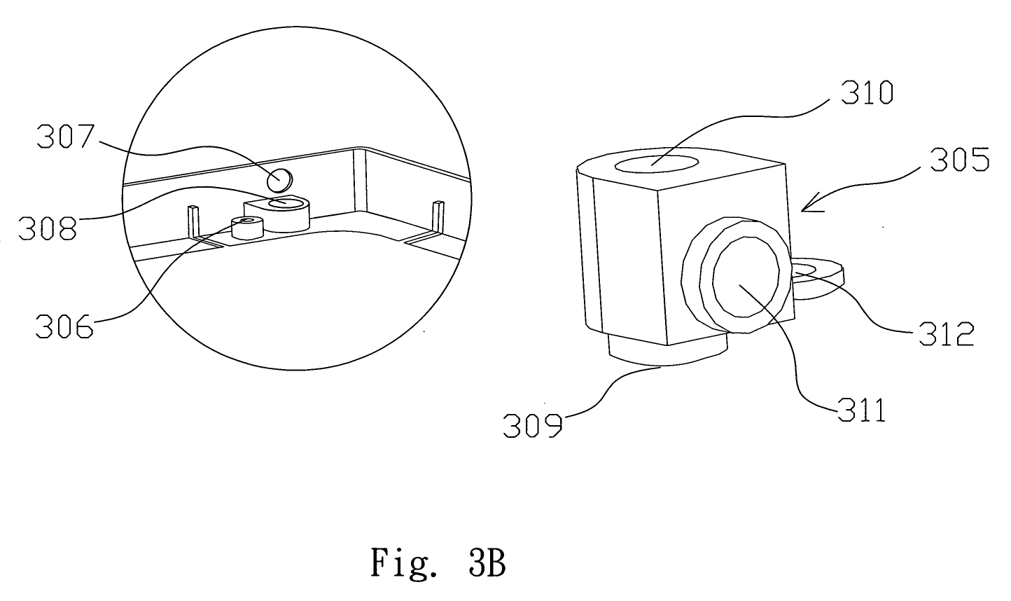

Refer to FIG. 3A for an exploded view schematically showing a second embodiment of the present invention. In the second embodiment, the coverless casing 301 is made of a plastic material instead of a metal. The plastic coverless casing 301 is a one-piece plastic coverless casing fabricated with an injection-molding process, which is a technology similar to the die-casting technology for the metallic coverless casing 201 in the first embodiment. The advantage of a plastic coverless casing is lightweight and low-cost. However, a plastic material is a poor heat and electric conductor. Since the plastic coverless casing 301 is free of a top cover, better air circulation can reduce the heat-conduction issue to a minimum.

To reduce the risk of ESD damage, two ground pin standing posts 305 are designed to electrically connect with the PCBA 302 via PCB screw holes 303 clad by ground planes to drain harmful ESD charges to the chassis ground of the host system before it strikes the electronic components of the solid state drive.

Refer to FIG. 3A and FIG. 3B. In this embodiment, the plastic coverless casing 301 has first casing holes 306, second casing holes 307 and third casing holes 308. The ground pin standing post 305 is made of copper or another metallic material and will be installed in the plastic coverless casing 301 before the PCBA 302 is installed in the plastic coverless casing 301. The ground pin standing post 305 has a pole 309, a first post hole 310, a second post hole 311, and a copper ring 312. The pole 309 is to be inserted into the third casing hole 308 on the plastic coverless casing 301 for mechanical support. A screw is screwed into a screw hole of the internal frame structure of the host system, the second casing hole 307 and the second post hole 311 to fasten the ground pin standing post 305 to the plastic coverless casing 301 and electrically connect the ground pin standing post 305 to a chassis ground of the host system. A screw is screwed into the PCB screw hole 303 clad by ground planes, the copper ring 312 and the first casing hole 306 of the plastic coverless casing 301 to electrically connect the PCBA 302 to the chassis ground of the host system via the ground pin standing post 305. The first post hole 310 is reserved for another device in host system to stack on it via screws when necessary.

In spite of the poor heat conduction of a plastic material, the SSD with a plastic coverless casing 301 of the present invention is also free of a top cover; thus, air circulation will be enhanced to reduce the heat-conduction problem and faster dissipate heat away from the SSD.

In spite of the poor electric conduction of a plastic material, the SSD with a plastic coverless casing 301 of the present invention has two ground pin standing posts 305 to bleed off the unwanted electro-static charges to the chassis ground of the host system.

Further, the SSD with a plastic coverless casing 301 of the present invention has the advantages of light weight and low cost.

Similarly, the SSD with a plastic coverless casing of the present invention can apply to a desktop computer, a notebook computer, or other portable electronic devices needing a memory drive.

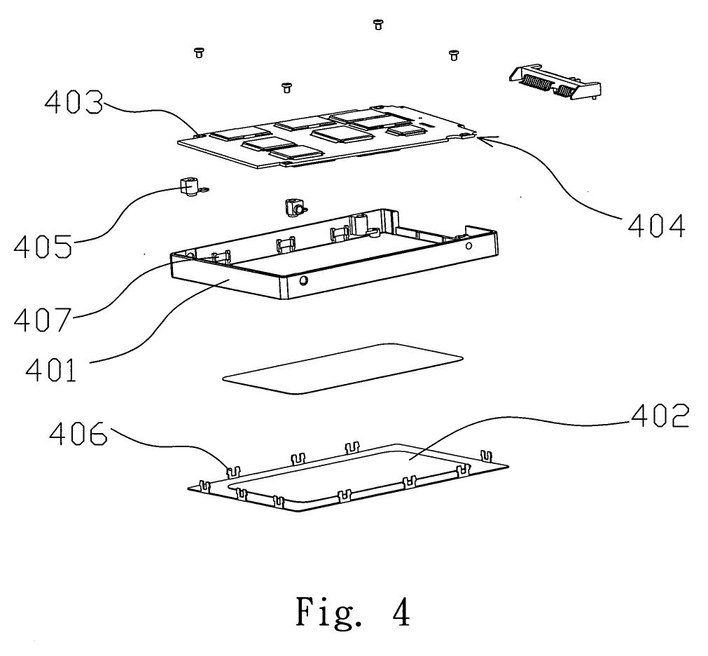

Refer to FIG. 4 for an exploded view schematically showing a third embodiment of the present invention. In the third embodiment, the coverless casing comprises: a plastic frame 401 and a sheet metal bottom 402.

The sheet metal bottom 402 has a plurality of snap hook fingers 406, which are arranged around the edges of the sheet metal bottom 402 and erected at a 90 degree angle with respect to the sheet metal bottom 402. On the bottom side of the plastic frame 401, there is a matching number of female slots 407 built at the exact positions to allow the snap hook fingers 406 to snap thereinto to form a hybrid coverless casing to house the PCBA 404.

The advantage of a plastic frame is lightweight and low-cost. However, a plastic material is a poor heat and electric conductor. Since there is no cover in the SSD of this embodiment, better air circulation can reduce the heat-conduction issue to a minimum.

In the third embodiment, there are also two ground pin standing posts 405 electrically connecting with the PCBA 404 via PCB screw holes 403 clad by ground planes to drain harmful ESD charges to the chassis ground of the host system before it strikes the electronic components of the solid state drive.

Similarly, the SSD with a hybrid coverless casing of the present invention can apply to a desktop computer, a notebook computer, or other portable electronic devices needing a memory drive.

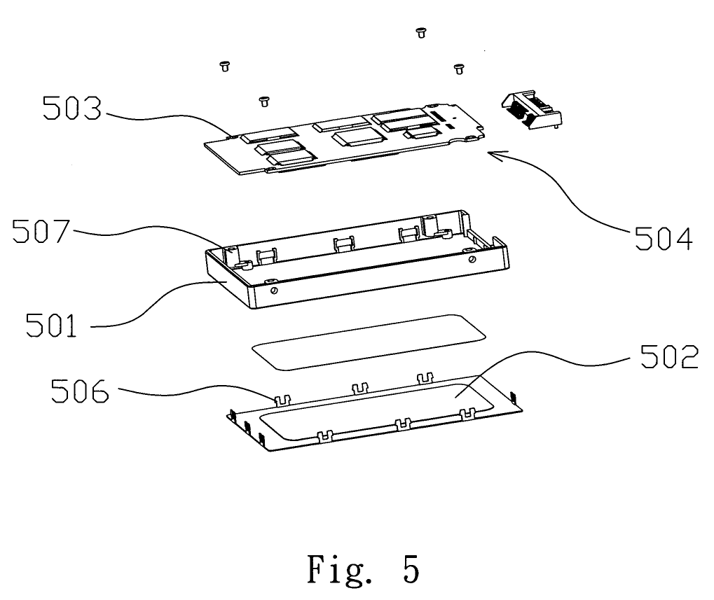

Refer to FIG. 5 for an exploded view schematically showing a fourth embodiment of the present invention. The fourth embodiment is basically similar to the third embodiment except a die-cast metallic frame 501 replaces the plastic frame 401 of the third embodiment. In the fourth embodiment, the coverless casing also comprises a sheet metal bottom 502. The sheet metal bottom 502 also has a plurality of snap hook fingers 506 to mate with female slots 507 of the die cast metal frame 501 to form a coverless casing to house the PCBA 504.

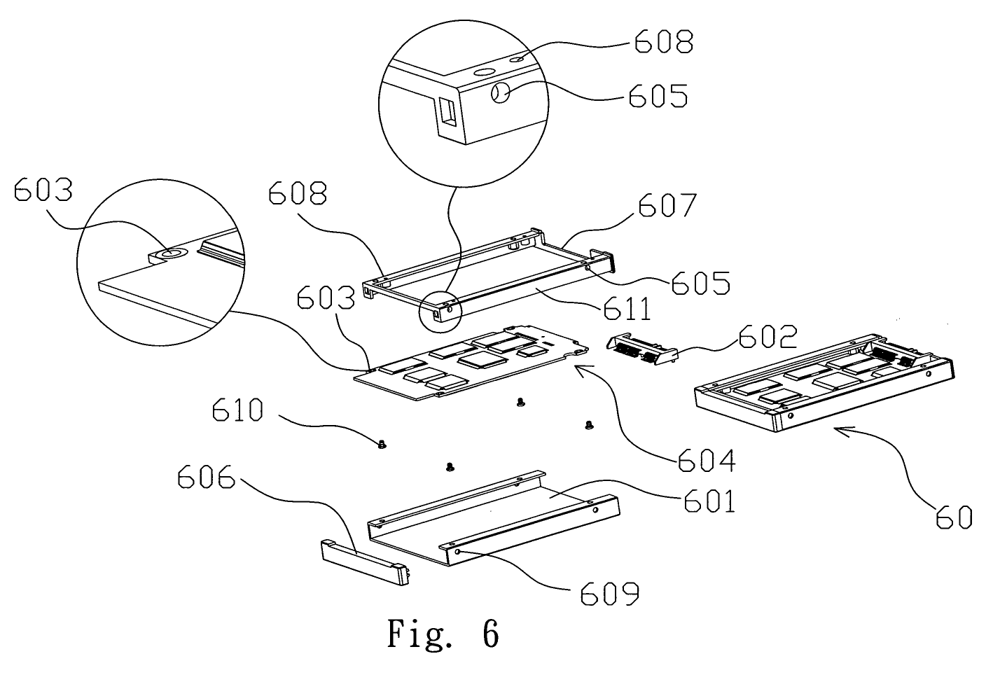

Refer to FIG. 6 for an exploded view schematically showing a fifth embodiment of the present invention. In the fifth embodiment, the coverless casing comprises: an aluminum-extrusion piece 601, a plastic end plug 606 and a plastic inner frame 611.

In assemblage, the PCBA 604 is fastened to the plastic inner frame 611 via screwing four screws 610 into the PCB through holes 603 and first plastic-frame holes 608. The sub-assembly is then slid into the aluminum extrusion piece 601, and one end of the plastic inner frame 611 is plugged up with end plug 606. The sub-assembly and the aluminum extrusion piece 601 are secured together via screwing four screws into metal-piece holes 609 and second plastic-frame hole 605. The connector 602 is seated snugly at a window slot 607 of the plastic inner frame 611. The SSD drive 60 is thus completed.

In conclusion, all the SSD's with a coverless casing disclosed in the present invention are free of a top cover; thereby, air circulation can be enhanced to faster dissipate heat away from the SSD's. Further, all the SSD's with a coverless casing of the present invention are designed to have PCBA electrically connected to the chassis ground of the host system via the coverless casings; thereby, unwanted electro-static charges can be dissipated to the chassis ground of the host system before electro-static charges can damage the electronic components on the PCBA. Furthermore, all the SSD's with a coverless casing of the present invention are made of lightweight materials and easy to fabricate and simple to assemble; therefore, all the SSD's with a coverless casing of the present invention have the advantages of light weight and low cost.

Those described above are only the preferred embodiments to exemplify the preset invention but not to limit the scope of the present invention. Any equivalent modification or variation according to the shapes, structures, characteristics or spirit disclosed in the present invention is also to be included within the scope of the present invention.

What is claimed is:

1. A solid state drive with a coverless casing, which is accommodated in an internal frame structure of a host system, comprising:
a printed circuit board assembly further comprising: a printed circuit board having a plurality of board screw holes clad by ground planes, at least one chip, passive components and at least one pin connector; and
a coverless casing and accommodating said printed circuit board assembly.

2. The solid state drive with a coverless casing according to claim 1, wherein said coverless casing is a one-piece metallic coverless casing fabricated with a die-casting process.

3. The solid state drive with a coverless casing according to claim 2, wherein said coverless casing is made of aluminum or electroplated with chromium.

4. The solid state drive with a coverless casing according to claim 2, further comprises a double side tape or an insulating material is used to separate said printed circuit board assembly from said coverless casing.

5. The solid state drive with a coverless casing according to claim 4, wherein said insulating material is a plastic, a rubber or a paper material.

6. The solid state drive with coverless casing according to claim 2, wherein a plurality of leveling posts projecting from inner side walls of said coverless casing is used to separate said printed circuit board assembly from said coverless casing and support said printed circuit board assembly at an elevated position.

7. The solid state drive with a coverless casing according to claim 2, wherein said coverless casing further comprises:
a plurality of screw poles allowing another device in said host system to be seated therein and serving as alignment guides for said printed circuit board assembly to sit at a precise position of said coverless casing;
an opened gap arranged at a back end wall of said coverless casing and allowing said pin connector to precisely fit thereinto;
a plurality of first screw holes arranged at four inner corners of said coverless casing, wherein screws are screwed into said board screw holes of said printed circuit board and said first screw holes to fasten said printed circuit board assembly firmly to said coverless casing; and
a plurality of second screw holes arranged at both lengthwise sides of said coverless casing, wherein screws are screwed into said second screw holes and screw holes of said internal frame structure of said host system to anchor said coverless casing to said internal frame structure of said host system.

8. The solid state drive with a coverless casing according to claim 7, wherein after screws are screwed into said board screw holes clad by said ground planes of said printed circuit board and said first screw holes of said metallic coverless casing, and after screws are screwed into said second screw holes and said screw holes of said internal frame structure of said host system, said printed circuit board assembly is electrically connected to said internal frame structure of said host system via said coverless casing to dissipate unwanted electro-static charges from said printed circuit board assembly to a chassis ground of said host system before electro-static charges damage electronic components on said printed circuit board assembly.

9. The solid state drive with coverless casing according to claim 7, wherein said screw poles allow a new solid state drive to be seated therein to form a memory drive stack.

10. The solid state drive with coverless casing according to claim 1, wherein said coverless casing is a plastic coverless casing.

11. The solid state drive with a coverless casing according to claim 10 further comprising at least one ground pin standing post, which is made of a metallic material and installed on said coverless casing before said printed circuit board assembly is installed in said coverless casing, wherein said ground pin standing post is used to electrically connect said printed circuit board assembly to said internal frame structure of said host system via at least one said board screw hole clad by said ground planes of said printed circuit board to drain electro-static charges to a chassis ground of said host system before electro-static charges strike electronic components on said printed circuit board assembly.

12. The solid state drive with a coverless casing according to claim 11, wherein said coverless casing further comprises: first casing holes, second casing holes and third casing holes; said ground pin standing post further comprises:
a pole inserted into said third casing hole for mechanical support;
a first post hole reserved for another device of said host system to stack thereon via screws;
a second post hole, wherein a screw is screwed into a screw hole of said internal frame structure of said host system, said second casing hole and said second post hole to fasten said ground pin standing post to said coverless casing and electrically connect said ground pin standing post to a chassis ground of said host system; and
a metallic ring, wherein a screw is screwed into said board screw hole clad by ground planes, said metallic ring and said first casing hole to electrically connect said printed circuit board assembly to said chassis ground of said host system via said ground pin standing post.

13. The solid state drive with a coverless casing according to claim 12, wherein said first post holes allow a new solid state drive to be seated therein to form a memory drive stack.

14. A solid state drive with a coverless casing according to claim 1, wherein said coverless casing is a hybrid coverless casing comprising:
a plastic frame and a sheet metal bottom, said sheet metal bottom is snap-fitted to said plastic frame to form said hybrid coverless casing.

15. The solid state drive with a coverless casing according to claim 14, wherein said sheet metal bottom has a plurality of snap hook fingers, which are arranged around edges of said sheet metal bottom and erected at a 90 degree angle with respect to said sheet metal bottom;
said plastic frame has a matching number of female slots built at corresponding positions to allow said snap hook fingers to snap thereinto to form said hybrid coverless casing.

16. The solid state drive with a coverless casing according to claim 14 further comprising at least one ground pin standing post, which is made of a metallic material and installed on said coverless casing before said printed circuit board assembly is installed in said coverless casing, wherein said ground pin standing post is used to electrically connect said printed circuit board assembly to said internal frame structure of said host system via at least one said board screw hole clad by said ground planes of said printed circuit board to drain electro-static charges to a chassis ground of said host system before electro-static charges strike electronic components on said printed circuit board assembly.

17. The solid state drive with a coverless casing according to claim 16, wherein said coverless casing further comprises: first casing holes, second casing holes and third casing holes; said ground pin standing post further comprises:
a pole inserted into said third casing hole for mechanical support;
a first post hole reserved for another device of said host system to stack thereon via screws;
a second post hole, wherein a screw is screwed into a screw hole of said internal frame structure of said host system, said second casing hole and said second post hole to fasten said ground pin standing post to said coverless casing and electrically connect said ground pin standing post to a chassis ground of said host system; and
a metallic ring, wherein a screw is screwed into said board screw hole clad by ground planes, said metallic ring and said first casing hole to electrically connect said printed circuit board assembly to said chassis ground of said host system.

18. The solid state drive with a coverless casing according to claim 1, wherein said coverless casing is a hybrid coverless casing comprising:
a die-cast metallic frame and a sheet metal bottom, said sheet metal bottom is snap-fitted to said die-cast metallic frame to form said hybrid coverless casing.

19. The solid state drive with a coverless casing according to claim 18, wherein said sheet metal bottom has a plurality of snap hook fingers, which are arranged around edges of said sheet metal bottom and erected at a 90 degree angle with respect to said sheet metal bottom; said die-cast metallic frame has a matching number of female slots built at corresponding positions to allow said snap hook fingers to snap thereinto to form said hybrid coverless casing.

20. The solid state drive with a coverless casing according to claim 1, wherein said coverless casing is a hybrid coverless casing comprising:
a plastic inner frame, an aluminum-extrusion piece, and a plastic end plug, and wherein said printed circuit board assembly is fastened to said plastic inner frame to form a sub-assembly via screwing screws into said board screw holes clad by ground planes of said printed circuit board and first holes of said plastic inner frame; said sub-assembly is slid into and fastened to said aluminum extrusion piece, and an end of said plastic inner frame is plugged up with said end plug.
